(19) United States
(12) Patent Application Publication
(10) Pub. No.: US 2013/0242149 A1
(43) Pub. Date: Sep. 19, 2013

(54) SOLID-STATE IMAGING ELEMENT AND METHOD FOR MANUFACTURING SAME

(71) Applicant: PANASONIC CORPORATION, Osaka (JP)

(72) Inventors: YUKA TERAI, Osaka (JP); ATSUO NAKAGAWA, Kyoto (JP)

(73) Assignee: Panasonic Corporation, Osaka (JP)

(21) Appl. No.: 13/887,731

(22) Filed: May 6, 2013

Related U.S. Application Data
(63) Continuation of application No. PCT/JP2011/004340, filed on Jul. 29, 2011.

(30) Foreign Application Priority Data
Dec. 1, 2010 (JP) 2010-268419

(51) Int. Cl. H04N 5/335; H01L 31/18

(52) U.S. Cl. CPC H04N 5/335; H01L 31/18
USPC 348/280; 348/273; 438/70

(57) ABSTRACT

A solid-state imaging device includes: a semiconductor substrate including a matrix of photoelectric converters disposed therein; a transparent insulating layer disposed on the semiconductor substrate and including wiring lines embedded therein; a color filter layer disposed on the transparent insulating layer and including a color filter for each of a plurality of colors of the respective photoelectric converters; and a plurality of microlenses disposed on the color filter layer, one for each color filter. In a plan view, the color filter of at least one color is smaller in area size than the corresponding microlens. In the color filter layer, the color filter of the at least one color is surrounded by a low-refractive-index material having a lower refractive index than a refractive index of the color filter.

### CROSS REFERENCE TO RELATED APPLICATION

This is a continuation application of PCT Application No. PCT/JP2011/004340 filed Jul. 29, 2011, designating the United States of America, the disclosure of which, including the specification, drawings and claims, is incorporated herein by reference in its entirety.

### TECHNICAL FIELD

The present disclosure relates to a solid-state imaging device having microlenses formed on color filters and also relates to a method for manufacturing such a solid-state imaging device.

### DESCRIPTION OF THE RELATED ART

Solid-state imaging devices are employed in digital still cameras, digital movie cameras, camera-equipped mobile phones, and so on. With the prevalence of these devices, there is a growing demand that solid-state imaging devices offer higher resolution and have a greater number of pixels. In response to this demand, an effort is underway to make pixels smaller and smaller.

Generally, a solid-state imaging device has: a semiconductor substrate in which a matrix of photoelectric converters is disposed, a transparent insulating layer having wiring liens embedded therein and disposed on the semiconductor substrate; color filters of colors determined for the respective photoelectric converters; and a plurality of microlenses disposed on the respective color filters (see Patent Literature 1, for example). A microlens is a convex lens for collecting incident light. Conventionally, microlenses are manufactured by a method involving a thermal reflow process in which, for example, a transparent resin material is melted by heat and then the surface tension of the molten material forms the curved surface of a lens.

The progress toward smaller pixels in recent years has also accelerated the progress toward smaller microlenses, as small as the order of a few micrometers in lens diameter.

### CITATION LIST

### Patent Literature

[Patent Literature 1]
Japanese Patent Application Publication No. 3-183165

### SUMMARY

In order to collect incident light to the photoelectric converters, desirable solid-state imaging devices are configured such that each microlens has a focus within the corresponding photoelectric converter disposed in the semiconductor substrate.

However, since the curved surfaces of the microlenses are formed through the thermal reflow process, it is difficult to control the formation of the microlenses to obtain a precise shape. Therefore, there may a case where the focus of a microlens falls in the corresponding color filter, which is located above the transparent insulating layer having wiring embedded therein. Naturally, light incident on a microlens is once converged and then diverged after it passes through the focus of the microlens. Therefore, when the focus is positioned in the color filter, a problem arises that divergence of light after it exits from the color filter becomes large.

This increase the risk of a phenomenon called “color crosstalk”, which is caused when the light exits from the color filter travels toward the wiring lines embedded in the transparent insulating layer and is reflected by the wiring liens to fall on the adjacent photoelectric converter. In the case where the solid-state imaging device is a CCD solid-state imaging device, the above problem leads to another risk that light may enter the vertical CCDs provided adjacent to each array of photoelectric converters, which results in occurrence of a phenomena called smear.

The present disclosure is made in view of the above and aims to provide a solid-state imaging device capable of suppressing divergence of light after the light exits a color filter, even if the focus of a microlens falls in the color filter. The present disclosure also aims to provide a method for manufacturing such a solid-state imaging device.

In order to solve the problems noted above, one aspect of the present disclosure provides a solid-state imaging device including: a semiconductor substrate including a matrix of photoelectric converters disposed therein; a transparent insulating layer disposed on the semiconductor substrate and including wiring lines embedded therein; a color filter layer disposed on the transparent insulating layer and including a color filter for each of a plurality of colors of the respective photoelectric converters; and a plurality of microlenses disposed on the color filter layer, one for each color filter. In a plan view, the color filter of at least one color is smaller in area size than the corresponding microlens. In the color filter layer, the color filter of the at least one color is surrounded by a low-refractive-index material having a lower refractive index than a refractive index of the color filter.

In another aspect, the present disclosure provides a manufacturing method for a solid-state imaging device, the manufacturing method including: a first step of forming a matrix of photoelectric converters in a semiconductor substrate; a second step of forming, on the semiconductor substrate, a transparent insulating layer containing wiring lines embedded therein; a third step of forming, on the transparent insulating substrate, a color filter layer including a color filter for each of a plurality of colors of the respective photoelectric converters; and a fourth step of forming a plurality of microlenses, one for each color filter. The third step includes: a step of forming the color filters each in a size smaller than the corresponding microlens in a plan view; and a step of disposing a low-refractive-index material to surround each color filter, the low-refractive-index material having a refractive index lower than a refractive index of the color filter.

In the solid-state imaging device having the above structure, the color filters of at least one color are each surrounded by a low-refractive-index material having a refractive index of the color filters themselves. Hence, the color filters of at least one color each act as a waveguide.

Therefore, even if the focus of a microlens is within such a color filter, light once converged at the focus is guided downward through the color filter. As a result, the divergence of light is suppressed as compared with the case where light diverges immediately after passing through the focus.

Consequently, the amount of light traveling toward wiring lines embedded in the transparent insulating layer is reduced, which is effective to suppress occurrence of color crosstalk resulting from light reflected by the wiring lines toward adjacent photoelectric converters. In addition, in the case of CCD solid-state imaging devices, the above structure is also effective to suppress occurrence of smear.

The manufacturing method for a solid-state imaging device having the above structure achieves the same advantageous effect as those achieved by the solid-state imaging device described above.

### BRIEF DESCRIPTION OF DRAWINGS

FIGS. 1A-1C are views showing a structure of a solid-state imaging device according to a first embodiment of the present disclosure.

FIG. 2A is a view illustrating how light diverges after passing through the focus in a conventional solid-state imaging device, and FIG. 2B is a view illustrating how light diverges after passing through the focus in the solid-state imaging device of the first embodiment.

FIGS. 3A and 3B are sectional views showing the electric field intensity distributions indicating the result of simulation run to confirm an effect to suppress divergence of light.

FIGS. 4A and 4B are views illustrating steps of a manufacturing method for the solid-state imaging device according to the first embodiment of the present disclosure.

FIGS. 5A and 5B are views illustrating subsequent steps of the manufacturing method shown in FIGS. 4A and 4B.

FIGS. 6A and 6B are views illustrating subsequent steps of the manufacturing method shown in FIGS. 5A and 5B.

FIGS. 7A and 7B are views illustrating subsequent steps of the manufacturing method shown in FIGS. 6A and 6B.

FIGS. 8A and 8B are views illustrating subsequent steps of the manufacturing method shown in FIGS. 7A and 7B.

FIGS. 9A and 9B are views illustrating subsequent steps of the manufacturing method shown in FIGS. 8A and 8B.

FIGS. 10A-10C are views showing a structure of a solid-state imaging device according to a second embodiment of the present disclosure.

FIGS. 11A and 11B are views illustrating steps of a manufacturing method for the solid-state imaging device according to the second embodiment of the present disclosure.

FIGS. 12A and 12B are views illustrating subsequent steps of the manufacturing method shown in FIGS. 11A and 11B.

FIGS. 13A-13C are views showing a structure of a solid-state imaging device according to a third embodiment of the present disclosure.

FIGS. 14A-14C are views showing a structure of a solid-state imaging device according to a fourth embodiment of the present disclosure.

FIGS. 15A-15C are views showing a structure of a solid-state imaging device according to a fifth embodiment of the present disclosure.

FIGS. 16A-16C are views showing a structure of a solid-state imaging device according to a sixth embodiment of the present disclosure.

FIGS. 17A-17C are views showing a structure of a solid-state imaging device according to a seventh embodiment of the present disclosure.

FIG. 18 is a sectional view showing the electric field intensity distributions indicating the result of simulation run to confirm an effect to suppress divergence of light.

### DETAILED DESCRIPTION

The following specifically describes embodiments of the present disclosure, with reference to the accompanying drawings.

### First Embodiment

### Overall Structure

A solid-state imaging device according to a first embodiment of the present disclosure is a CCD solid-state imaging device and includes a matrix of pixels, such as 2048×1536 pixels (about three million pixels), for example.

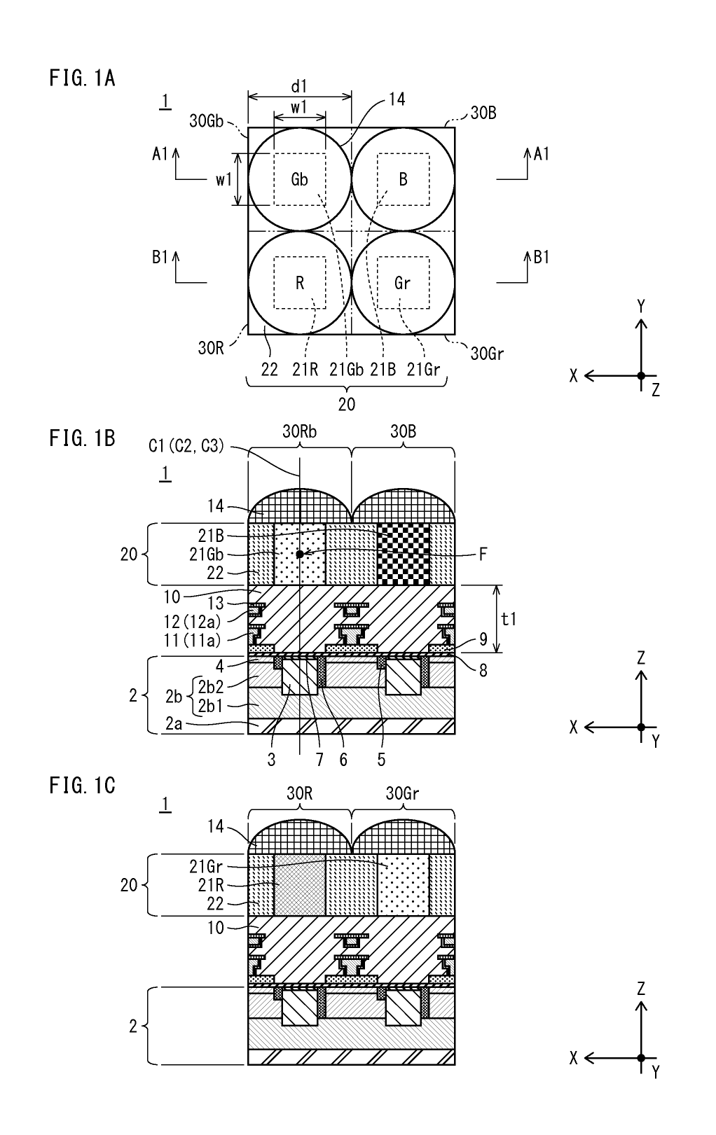

FIG. 1A is a top view showing part of the solid-state imaging device according to the first embodiment. More specifically, a region corresponding 2×2 pixels are shown, out of the plurality of pixels. FIG. 1B is a sectional view taken along the arrowed line A1-A1 of FIG. 1A, whereas FIG. 1C is a sectional view taken along the arrowed line B1-B1 of FIG. 1A.

As shown in FIG. 1A, the solid-state imaging device 1 has red pixels 30R, green pixels 30Gr and 30Gb, and blue pixels 30B. These pixels 30R, 30Gr, 30Gb, and 30B are arranged in a Bayer array.

As shown in FIGS. 1B and 1C, the solid-state imaging device 1 includes a silicon substrate 2, which is a semiconductor substrate. The silicon substrate 2 has an N-type region 2a and a P-type well region 2b that is on the N-type region 2a.

The P-type well region 2b has a two-layer structure formed form a first well region 2b1 on the N-type region 2a and a second well region 2b2 on the first well region 2b1. Disposed in the second well region 2b2 are photodiodes 3, transfer channels 4, Vt control regions 5, channel stop regions 6, and P+ layers 7.

The photodiodes 3 are arranged in a matrix. The transfer channels 4 are shaped into straight lines and disposed adjacent to the respective arrays of the photodiodes 3. The transfer channels 4 constitute part of vertical CCDs.

Each Vt control region 5 is disposed between a photodiode 3 and a transfer channel 4 adjacent to the photodiode 3. Each channel stop region 6 is disposed at the side of a photodiode 3 opposite from the Vt control region 5. The P+ layers 7 are disposed on the respective photodiodes 3 to extend internally along the upper surface of the silicon substrate 2.

An insulating film 8 made from silicon oxide is disposed on the silicon substrate 2. On the insulating film 8, transfer electrodes 9 are disposed one for each photodiode 3 and at a location corresponding to a gap between two adjacent arrays of the photodiodes 3. Together with the transfer channels 4 of each array, the transfer electrodes 9 in the corresponding array constitute the vertical CCDs.

A transparent insulating layer 10 made from silicon oxide is disposed on the transfer electrodes 9 and the insulating film 8. In the transparent insulating layer 10, first wiring lines 11 and second wiring lines 12 are embedded.

The first wiring lines 11 are provided for the respective rows of the transfer electrodes 9. To read out signal charge generated by the photodiodes 3, a drive pulse is applied to the respective transfer electrodes 9 via the first wiring lines 11. The second wiring lines 12 are provided for the respective first wiring lines 11 and connected in parallel to the respective first wiring line 11.

The first and second wiring lines 11 and 12 are made of copper and coated with a barrier film 13. The barrier film 13 is provided for preventing copper contained in the wiring lines 11 and 12 from diffusing into silicon oxide constituting the transparent insulating layer 10.

A color filter layer 20 is disposed on the transparent insulating layer 10, and the color filter layer 20 includes color filters 21R, 21Gr, 21Gb, and 21B provided for the respective photodiodes 3. In the following description, the color filters 21R, 21Gr, 21Gb, and 21B may be collectively referred to as the “color filters 21”.

Disposed on the color filter layer 20 are microlenses 14 provided for the respective color filters 21.

### <Structure of Microlenses>

Each microlens 14 is a convex lens formed from a transparent resin material by a thermal reflow process. The microlens 14 has a diameter d1 that measures 1.5 VIM.

The microlens 14 has a curved surface, the shape of which is determined depending on the balance between the surface tension and the dead weight of the transparent resin material in the thermally molten state. That is, for a lens of a smaller diameter, the weight of the transparent resin material is lighter, which naturally leads a relatively greater surface tension. Thus, the surface (curvature) of the resulting lens approaches a spherical shape, which means that the focal length of the lens is shorter.

To collect light to the photodiodes 3, it is ideal that the focus position of each microlens 14 is located in a photodiode 3. According to the present embodiment, however, the diameter d1 of each microlens 14 is as short as 1.5 μm and the focal length is shorter than the distance from the microlens 14 to the photodiode 3. That is to say, the position of the focus F1 of the microlens 14 is not within the photodiode 3 but above the photodiode 3. The description of the present embodiment is given on condition that the position of the focus F1 of each microlens 14 is in a corresponding one of the color filters 21.

In the case where light converges to one point, the term “focus of a microlens” refers to that point. In the case where light does not converges to one point due to spherical aberration of the lens, the term refers to a central point of where the light most tightly converges.

### <Structure of Color Filters>

The following now describes the color filter layer 20.

The color filters 21R, 21Gr, 21Gb, and 21B all have the same dimensions and a square shape in a plan view. The width w1 of the squared shaped color filters 21R, 21Gr, 21Gb, and 21B is smaller than the diameter d1 of the microlenses 14.

In the color filter layer 20, each color filter 21 is surrounded on the four sides by a low-refractive-index material 22, which is a material having a refractive index lower than that of the color filters 21. With this arrangement, the color filters 21 act as waveguides that guide light incident on the respective color filters 21 to a downward position by confining the light due to total reflection or Fresnel reflection at the boundaries with the low-refractive-index material 22.

In one example, the color filters 21 are made from an organic material containing pigments dispersed therein, and the low-refractive-index material 22 is a transparent material such as organic glass material.

In the present embodiment, the refractive index of the color filters 21 is in the range of 1.4 to 1.9, while the refractive index of the low-refractive-index material 22 is in the range of 1.0 to 1.2.

In addition, the central axis c1 of each color filter 21 is set to be coaxial with the optical axis c2 of the corresponding microlens 14 and also with the central axis c3 of the corresponding photodiode 3 (see the pixel 30Gb shown in FIG. 1B). Note that the optical axis c2 is set to pass the center of the microlens 14 in a plan view (i.e., the areal gravity center of the microlens 14) and to be perpendicular to the upper surface of the silicon substrate 2.

The “central axis c1 of a color filter 21” refers to the axis that passes through the center of the color filter 21 in a plan view (i.e., the areal gravity center of the color filter 21) and is perpendicular to the upper surface of the silicon substrate 2. In addition, the “central axis c3 of a photodiode 3” refers to the axis that passes through the center of the photodiode 3 in a plan view (i.e., the areal gravity center of the photodiode 3) and is perpendicular to the upper surface of the silicon substrate 2.

In addition, the phrase that “the central axis c1 is coaxial with the optical axis c2 and the central axis c3” encompasses not only the positional relation in which the central axis c1 is completely coaxial with the optical axis c2 and the central axis c3 but also the positional relation involving some deviation due to, for example, manufacturing errors, despite that the intended designed is to have the completely coaxial positional relation. Note that the all of the pixels of the solid-state imaging device 1 may be designed to ensure that “the central axis c1 is coaxial with the optical axis c2 and the central axis c3” or alternatively, such design may be applied only to some of pixels of the solid-state imaging device 1. Suppose, for example, that the solid-state imaging device 1 is applied to a digital camera. In this case, it is preferable that some of the pixels of the solid-state imaging device 1, more specifically, those pixels located in a central region of the pixel matrix have the completely coaxial positional relation. In this case, it is also preferable that the rest of the pixels (those located in the peripheral region of the pixel matrix) be structured such that the optical axis c2 is inclined relative to the central axes c1 and c3 by 8 degrees or so, in consideration of the fact that light from the camera lens enters those peripheral pixels at an angle.

According to the present embodiment, the width w1 of the color filters 21 is in a range of 0.4 to 1.0 μm, which is smaller than the diameter d1, and the thickness t1 of the color filters 21 is in a range of 0.4 to 0.9 μm.

Here, the width w1 of the color filters 21 is not merely smaller than the diameter d1. Rather, the width w1 is set to be the size comparable to the wavelength of visible light (0.4 to 1.0 μm). This arrangement is preferable in that propagation of light within the color filters 21 acting as waveguides is ensured to be single-mode propagation or nearly single-mode propagation.

### ADVANTAGE

Even with the solid-state imaging device 1 having the above structure, it still holds that light once converged by each microlens 14 diverges after it passes through the focus F1 located in the corresponding color filter 21. Yet, since the color filters 21 are surrounded by the low-refractive-index material 22 and thus act as waveguides, the divergence of light passing through the color filters is smaller than that observed in a conventional solid-state imaging device.

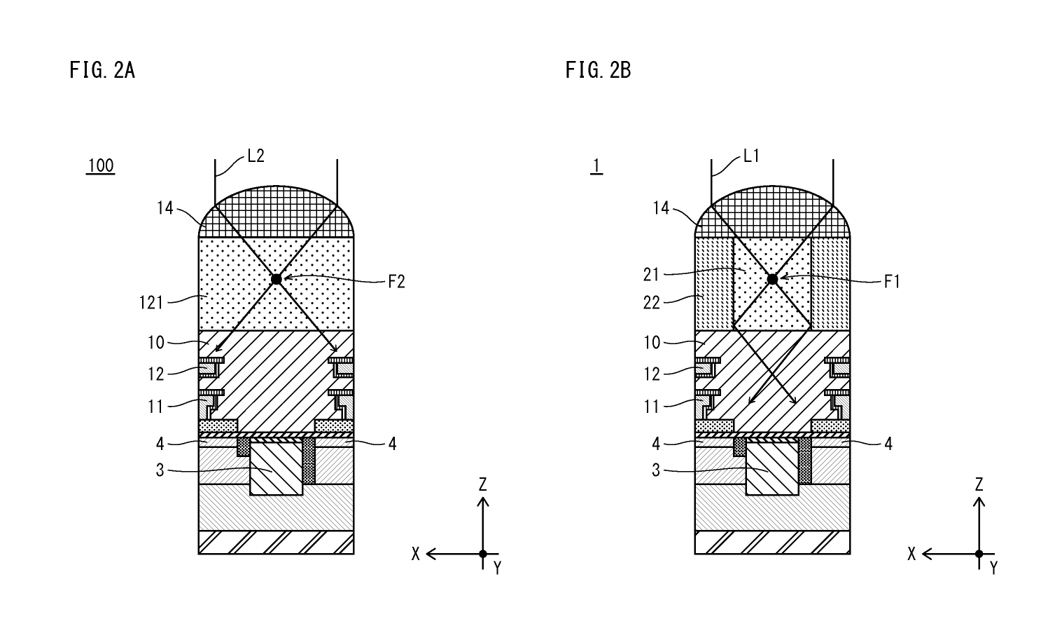

This effect to suppress divergence of light is described in detail with reference to FIG. 2.

FIG. 2A illustrates how light diverges after passing through the focus in a conventional solid-state imaging device. FIG. 2B illustrates how light diverges after passing through the focus in the solid-state imaging device 1 according to the present embodiment. The solid-state imaging devices shown in FIGS. 2A and 2B differ in the structure of the color filters and identical in the other respects.

The conventional solid-state imaging device 100 shown in FIG. 2A has a color filter 121 having a width equal to the diameter of the microlens 14. That is, the color filter 121 is not constructed to act as a waveguide. The focus F2 of the microlens 14 is located in the color filter 121. In the conventional solid-state imaging device 100, for example, rays of incident light L2 pass through the focus F2 and keep traveling straight. Therefore, rays of light converged to the focus F2 by the microlens 14 diverge after passing through the focus F2. In the solid-state imaging device 1 according to the present embodiment, although rays of incident light L1 are converged to the focus F1 by the microlens 14 and then diverge, as shown in FIG. 2B, the rays of incident light L1 are thereafter reflected from the boundaries between the color filter 21 and the low-refractive-index material 22 due to total reflection or Fresnel reflection. That is, the divergence of light passing through the color filter is made smaller as compared with that observed in the conventional solid-state imaging device 100.

As a consequence, the amount of light, such as the rays of incident light L2 shown in FIG. 2A, traveling toward the wiring lines 11 and 12 embedded in the transparent insulating layer 10 is reduced. This leads to suppress occurrences of color crosstalk resulting from that light is reflected by the wiring lines 11 and 12 and enters into an adjacent photodiode 3. In addition, the amount of light traveling toward the transfer channel 4 of the vertical CCD that is adjacent to the photodiode 3 is also reduced. This leads to suppress occurrences of smear. It reversely means that the amount of light traveling toward the photodiode 3 is increased, so that the collection efficiency of light to the photodiode 3 is improved.

The following describes the result of simulation run to confirm the effect to suppress divergence of light.

This simulation was performed to obtain electric field intensity distributions of a working example that is a solid-state imaging device having a color filter acting as a waveguide and of a comparative example that is a solid-state imaging device having a color filter not acting as a waveguide.

More specifically, the electric field intensity distributions in a red pixel region exhibited upon receipt of red light (at a wavelength of 600 nm) were simulated on the respective solid-state imaging devices of the working example and comparative example.

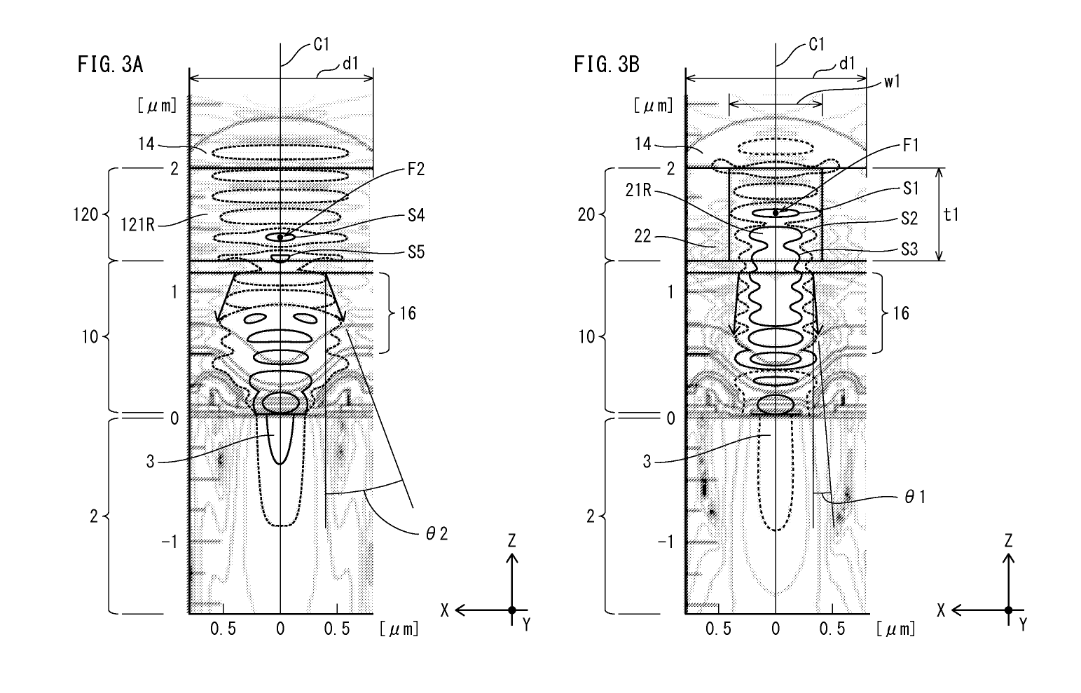

FIGS. 3A and 3B are obtained through the simulations. More specifically, FIG. 3A is a sectional view showing the electric field intensity distribution simulated for the comparative example, and FIG. 3B is a sectional view showing the electric field intensity distribution simulated for the working example. The vertical axis represents the height or equivalently the depth from the top surface of the silicon substrate. The horizontal axis represents the distance from the central axis c1 of the photodiode 3.

The respective solid-state imaging devices of the working example and the comparative example differ in the structure of the color filters and identical in the other respects. In addition, as shown in FIG. 3B, the solid-state imaging device of the working example is basically identical in structure to the solid-state imaging device 1 shown in FIGS. 1A-1C, except that intra-layer lenses 16 are embedded in the transparent insulating layer 10. The solid-state imaging device of the comparative example also has intra-layer lenses 16 embedded in the transparent insulating layer 10. Therefore, the presence of intra-layer lenses is considered to have no substantial impact on the comparison of the working example and the comparative example for their respective effects to suppress divergence of light.

The width w1 of the color filter 21R used in the working example is 0.75 μm. The width of the color filter 121R used in the comparative example was equal to the diameter d1 (1.5 μm) of the microlens 14. In addition, the thickness t1 of the color filters 21R and 121R was 0.75 μm. The refractive index of the color filters 21R and 121R was 1.6, and the refractive index of the low-refractive-index material 22 was 1.2.

In FIGS. 3A and 3B, the electric field intensity distributions are shown by contour lines. In addition, to clearly show the region where the electric field intensity is high, “bold lines” are used to indicate the highest electric field intensity, “broken lines” are used to indicate the second-highest electric field intensity, and “thin lines” are used for all the other contour lines. In other words, a region bounded by a bold line is where the light intensity is highest.

First, the electric field intensity distribution of light within each color filter is discussed.

In the color filter 121R of the comparative example shown in FIG. 3A, regions s4 and s5 bounded by a bold line are where the electric field intensity is high. One of the regions s4 and s5 appears to surround the focus F2, and the other appears below the focus F2. On the other hand, in the color filter 21R of the working example shown in FIG. 3B, regions s1, s2, and s3 bounded by a bold line are where the electric field intensity is high. One of the regions s1, s2, and s3 appears to surround the focus F1 and the others appear below the focus F1. The regions s1-s3 are significantly larger in size than the regions s4 and s5 observed in the comparative example. This result indicates that the divergence of light was duly suppressed. More specifically, in the working example, the divergence of light having passed through the focus F1 was suppressed, so that loss of light intensity within the color filter 21R was prevented and hence the electric field intensity was maintained high.

Note that the focus F1 of the working example is at a height (position) different from the focus F2 of the comparative example. This is because, unlike the comparative example, the working example is configured such that a portion of light incident on the microlens enters the color filter via a low-refractive-index material.

In addition, the color filter 21R of the working example exhibited the electric field intensity distribution in which a plurality of horizontally elongated regions bounded by a broken line (i.e., the regions with second-highest electric field strength) appear at locations along a vertical direction (Z-axis direction) from one edge to the other edge of the color filter 21. This indicates the occurrence of standing waves within the color filter 21R.

Next, the electric field intensity distribution of light emerging from each color filter is discussed.

In the transparent insulating layer 10 of the comparative example shown in FIG. 3A, a portion of light from the color filter 121R diverges to travel toward the wiring line 11 (at the divergent angle θ2). To permit easy comparison with the working example, the “divergent angle” used herein is the “divergent angle” of a region bounded by a broken line.

In the transparent insulating layer 10 of the working example shown in FIG. 3B, on the other hand, light from the color filter 21R diverges to some extent (with the divergent angle θ1), none of the light travels toward the wiring line 11. As clarified above, the working example succeeded in keeping the divergent angle θ1 of light emerged from the color filter smaller than the divergent angle θ2 in the comparative example.

The following are assumed to be the reason that the working example successfully suppressed the divergence of light.

The width w1 of the color filter 21R of the working example was 0.75 μm, which was close to the size of the wavelength of red light being incident light (600 nm). As a consequence, the propagation mode of the color filter 21R acting as a waveguide was ensured to be single-mode propagation or nearly single-mode propagation, which is advantageous for suppressing divergence of light.

More specifically, the single-mode propagation is known to have an electric field intensity distribution which is analogous to the Gaussian distribution. In accordance with the Gaussian distribution, the electric field intensity within the waveguide is highest at its center and gradually becomes lower toward the periphery. Here, looking at the inside of the color filter 21R (the region below the focus F1) in FIG. 3B, it is noted that the central portion of the color filter 21R includes regions s1-s3 bounded by a bold line, and those regions s1-s3 are surrounded by regions bounded by a broken lines. That is, the electric field intensity within the color filter 21R is gradually lower from the center toward the periphery. Therefore, the electric field intensity distribution shown in FIG. 3B is considered to be analogous to the Gaussian distribution, which leads to a conclusion that the propagation mode of the working example is single-mode propagation or nearly single-mode propagation. In the single-mode propagation, the intensity of light within the waveguide is lower at the peripheral portion that at the central portion. Therefore, divergence of light is said to be smaller in the single-mode propagation than that in multi-mode propagation. In addition, although light emitted from the waveguide still diverges due to diffraction, the influence of diffraction remains small because the intensity of light at the peripheral portion is lower and thus the extent of light divergence is kept small.

The simulation results described above confirm that the effect to suppress divergence of light is achieved by the present embodiment.

### <Manufacturing Method>

Next, a description is given of a manufacturing method for the solid-state imaging device 1 according to the present embodiment.

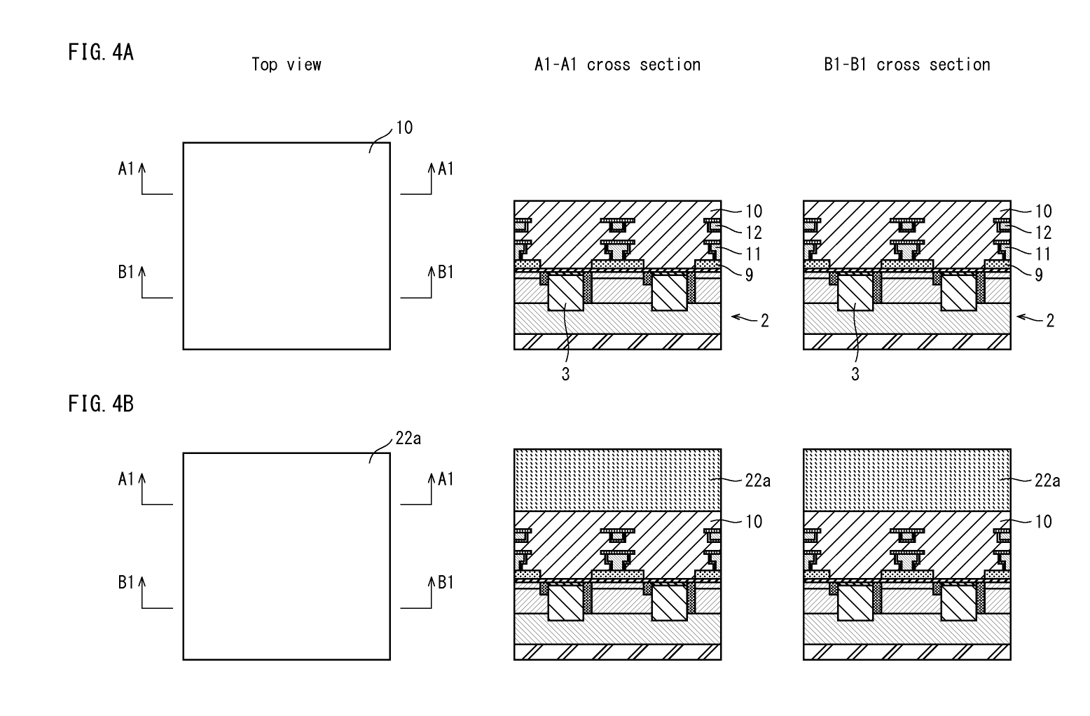

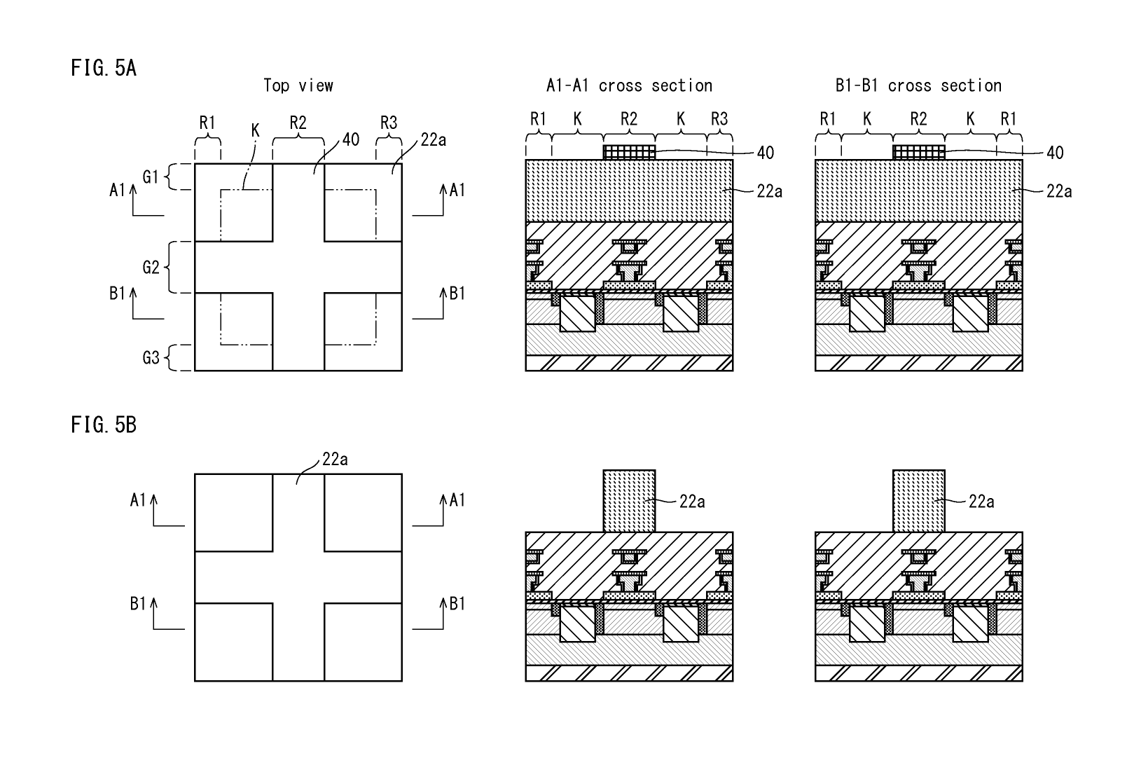

FIGS. 4-9 are schematic sectional views used to explain the manufacturing method for the solid-state imaging device 1. FIG. 4A includes a top view of the solid-state imaging device 1 as well as two sectional views, one taken along the arrowed line A1-A1 and the other along the arrowed line B1-B1 of the top view. The same applies to FIG. 4B and also to FIGS. 5-9.

### <<First Step>>

First, the respective regions, such as photodiodes 3, are formed in the silicon substrate 2 (FIG. 4A).

### <<Second Step>>

Subsequently, an insulating film, transfer electrodes 9, wiring lines 11 and 12, and a transparent insulating layer 10 are formed over (i.e., on or above) the silicon substrate 2 (FIG. 4A).

### <<Third Step>>

The next step is to form color filter layers 20.

### (First Sub-Step of Disposing Low-Refractive-Index Material)

First, a low-refractive-index material 22a is applied to the entire upper surface of the transparent insulating layer 10 (FIG. 4B), and then a resist pattern 40 is formed on the low-refractive-index material 22a (FIG. 5A).

Here, regions of the low-refractive-index material 22a each corresponding to where the respective color filters 21 are to be formed in a matrix are referred to as formation regions K. Regions between any two adjacent rows of formation regions K are referred to as row-spacing regions G1-G3. Regions between any two columns of adjacent formation regions K are referred to as column-spacing regions R1-R3. Then, the resist pattern 40 is formed to cover even-numbered row-spacing regions and even-numbered column-spacing regions (that is, the row-spacing region G2 and the column-spacing region R2).

Then, the low-refractive-index material 22a is processed by dry etching with the use of the resist pattern 40 to remove exposed regions of the low-refractive-index material 22a, namely the formation regions K for the color filters 21, row-spacing regions G1 and G3, and column-spacing regions R1 and R3 (FIG. 5B).

In this manner, since the regions to be removed are made greater by including the row-spacing regions G1 and G3 and the column-spacing regions R1 and R3 of the low-refractive-index material 22a as well as the formation regions K of the color filters 21, the etching is carried out more easily. This arrangement helps to accurately reserve the formation regions K for the color filters 21 and thus helps to accurately form the color filters 21.

### (Color Filter Forming Step)

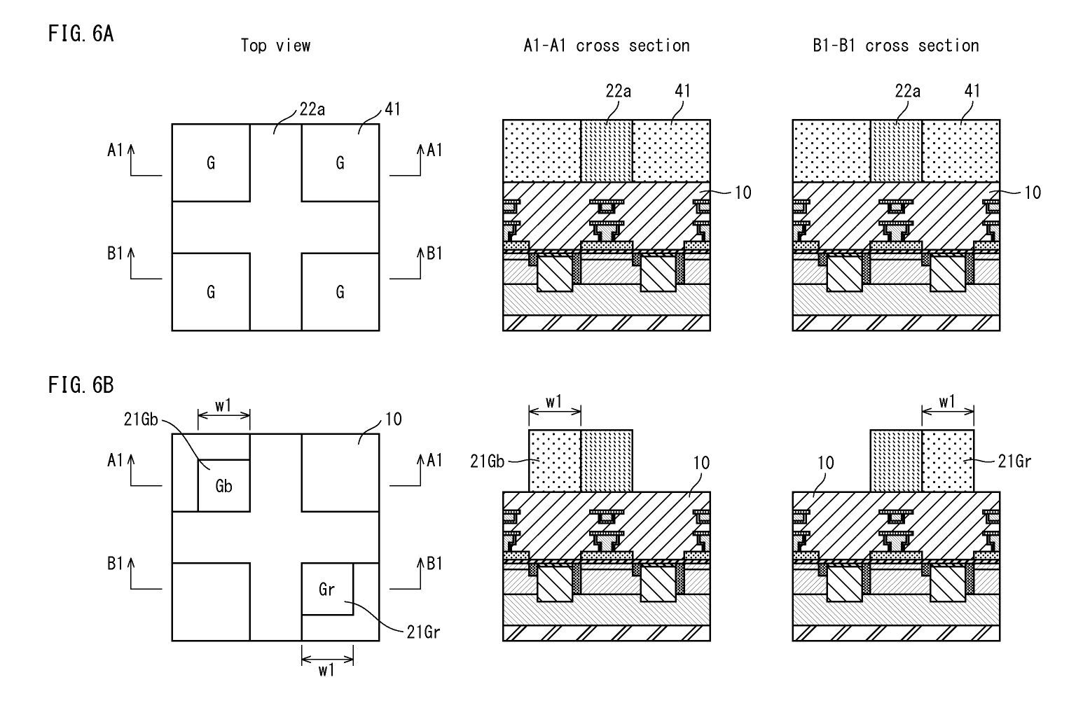

First, a green color filter material 41 containing photosensitizer is applied to the regions of the transparent insulating layer 10 excluding where low-refractive-index material 22a is present (FIG. 6A). Then, the color filter material 41 is exposed to a pattern of light to form color filters 21Gr and 21Gb (FIG. 6B).

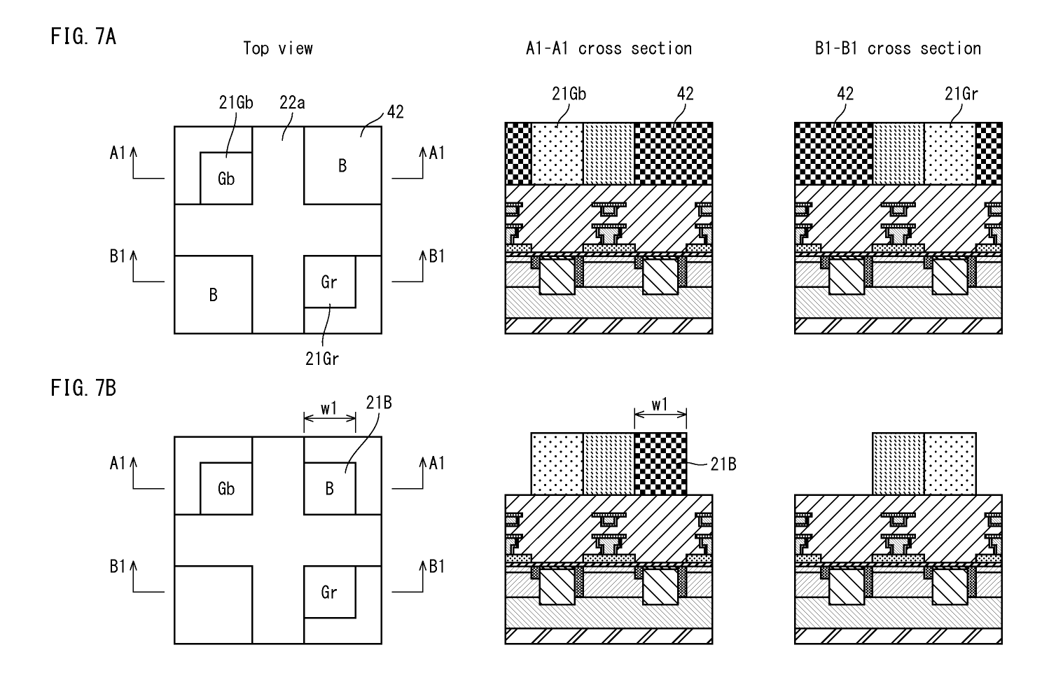

Next, a blue color filter material 42 containing photosensitizer is applied to the regions of the transparent insulating layer 10 excluding where the low-refractive-index material 22a and the color filters 21Gr and 21Gb are present (FIG. 7A). Then, the color filter material 42 is patterned to form color filters 21B (FIG. 7B).

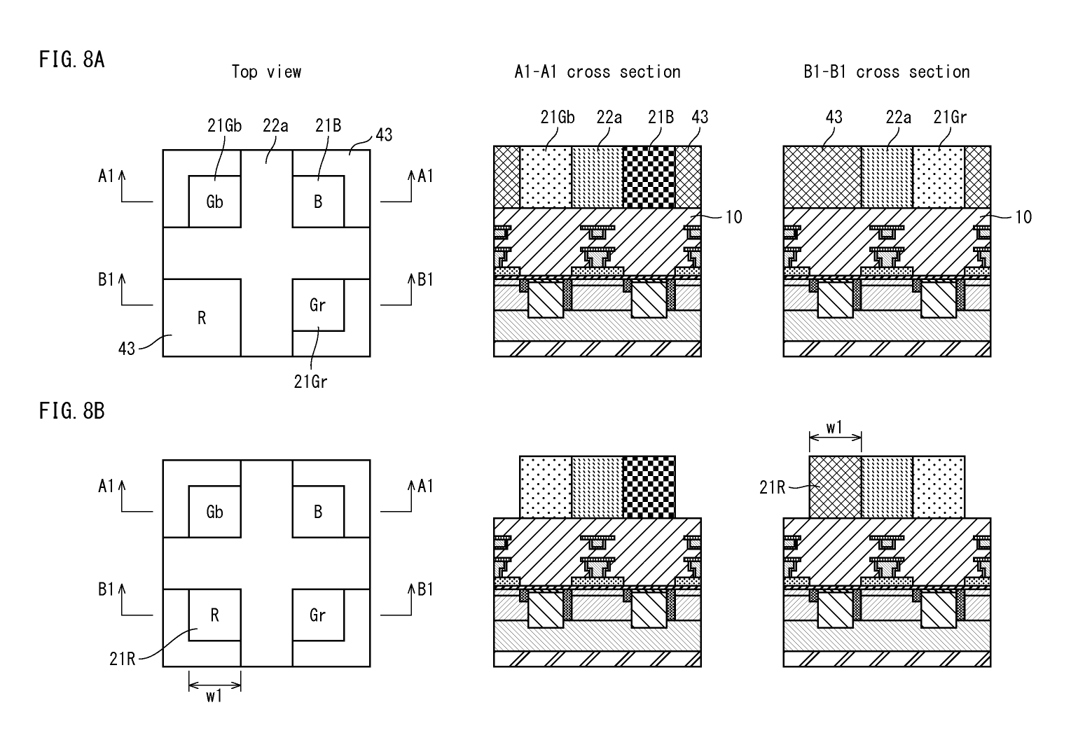

Next, a red color filter material 43 containing photosensitizer is applied to the regions of the transparent insulating layer 10 excluding where the low-refractive-index material 22a and the color filters 21Gr, 21Gb, and 21B are present (FIG. 8A). Then, the color filter material 43 is patterned to form color filters 21R (FIG. 8B).

The color filters 21 of the respective colors are formed such that the width w1 of the color filters 21 is smaller than the diameter d1 of the microlenses 14. The order in which the respective color filters 21 are formed is not limited to the order described above.

### (Second Sub-Step of Disposing Low-Refractive-Index Material)

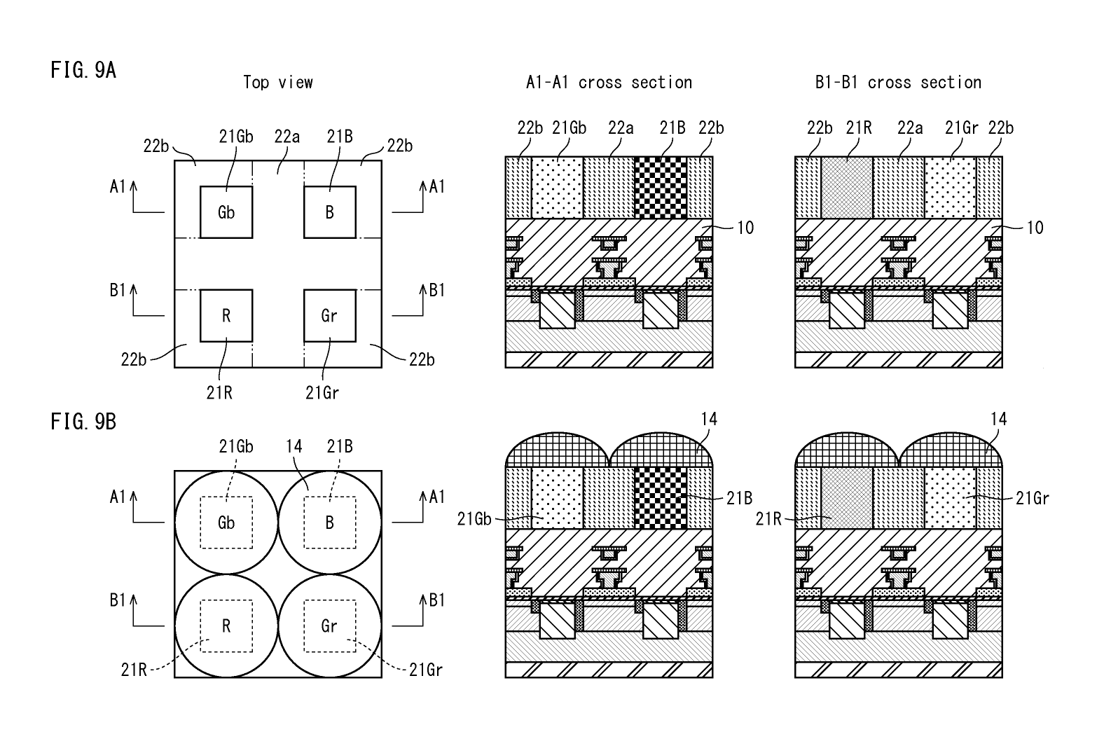

First, low-refractive-index material 22b of identical compositions as the low-refractive-index material 22a is applied to the regions of the transparent insulating layer 10 excluding where the low-refractive-index material 22a and the color filters 21 are present (FIG. 9A). Through this sub-step, the color filters 21R, 21Gr, 21Gb, and 21B are surrounded by the low-refractive-index material 22, which has been applied as the low-refractive-index materials 22a and 22b.

### <<Fourth Step>>

Finally, microlenses 14 are formed on the respective color filters 21R, 21Gr, 21Gb, and 21B (FIG. 9B).

Through the above steps, the solid-state imaging device 1 is manufactured.

### Second Embodiment

### Schematic Structure

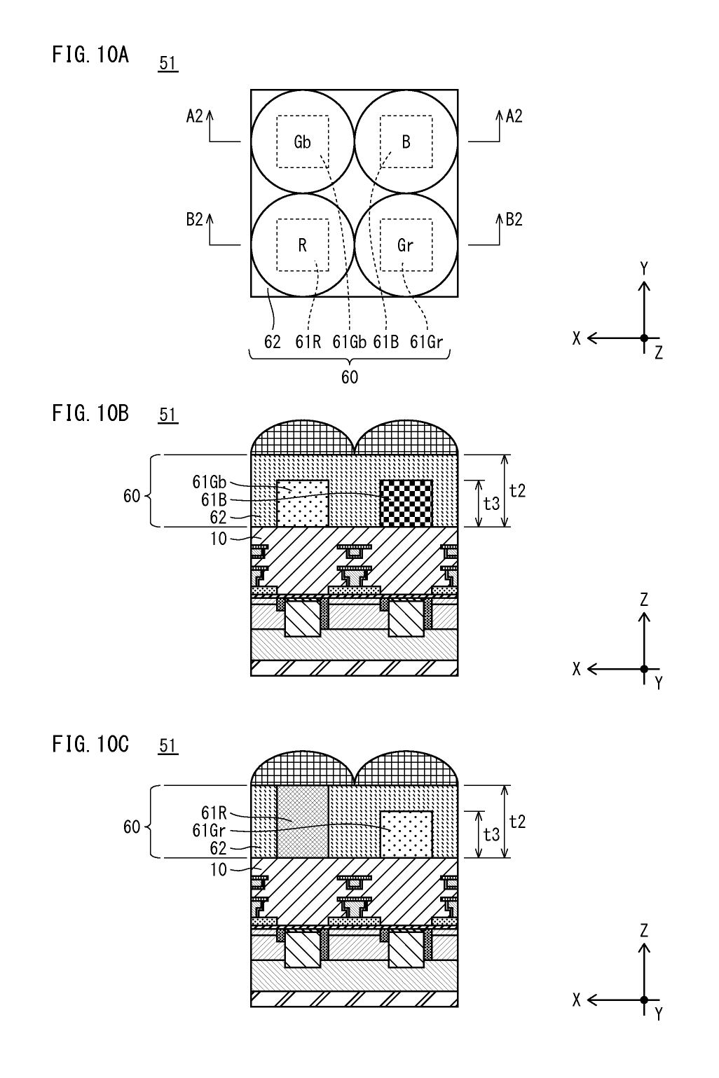

Next, a description is given of a solid-state imaging device 51 according to a second embodiment of the present disclosure, with reference to FIGS. 10A-10C.

FIG. 10A is a top view showing part of the solid-state imaging device according to the second embodiment. FIG. 10B is a sectional view taken along the arrowed line A2-A2 of FIG. 10A, whereas FIG. 10C is a sectional view taken along the arrowed line B2-B2 of FIG. 10A.

According to the first embodiment, the respective color filters 21R-21B are all equal in thickness. Yet, the present embodiment differs from the first embodiment in that the thickness t2 of red color filters 61R is greater than the thickness t3 of green and blue color filters 61Gr-61B. For the sake of simplicity, the components identical to those of the solid-state imaging device 1 shown in FIGS. 1A-1C are denoted by the same reference signs and a description thereof is omitted.

### <Structure of Color Filters>

The color filter layer 60 includes the red color filters 61R as well as the color filters 61Gr-61B of the other colors all disposed on the transparent insulating layer 10. That is, the color filters 61R, which are thicker, project upwardly beyond the color filters 61Gr-61B. In order to provide the color filter layer 60 with a flat surface, a low-refractive-index material 62 surrounding the color filters 61 is filled to the same height as the upper surfaces of the color filters 61R.

The following describes the reason for forming the color filters 61R to have a thickness different from the thickness of the color filters 61Gr-61B of the other colors.

Preferably, the thickness of a color filter is set according to the wavelength of light that can transmit the color filter. More specifically, the preferable thickness of a color filter is an integral multiple of a half of the wavelength of transmission light of the color filter. Note that the “wavelength of transmission light of the color filter” refers to the dominant wavelength of light that can transmit the color filter and that calculated in consideration of the refractive-index of the color filter.

That is, light that transmits the respective color filters is a mixture of light that exits from the color filter without being reflected at the boundary at the bottom surface of the color filter and light that exits from the color filter after being reflected back and force within the color filter. The thickness of the color filter is defined so as not to cause phase difference between the respective rays of light and thereby to amplify the respective rays of light transmitted. As a result, the amount of light to be transmitted is increased.

However, the following should be noted in manufacturing of the color filters of the respective colors having different thickness. That is, since a step of providing a flat surface (by filing with low-refractive-index material, for example) needs to be performed separately for the color filters of the respective thicknesses, the manufacturing load increases. In order to suppress the manufacturing load, the present embodiment limits the number of different thicknesses of the color filters. More specifically, the present embodiment provides the color filters in two different thicknesses (namely, the red color filters in a certain thickness, and the color filters of the other colors in a different thickness). The following describes the reason for providing the red color filters in a thickness that is different from the color filters of the other colors. That is, since its wavelengths are longer than light of other colors, red light is diffracted more than other colors of light when passing through a color filter. Naturally, the amount of light traveling toward the corresponding photodiode is smaller as compared with light of the other colors. To compensate for the loss, it is preferable to increase the amount of light to transmit the red filters. From the viewpoint of increasing the amount of light transmitted, it is preferable that the color filters have different thicknesses for the respective colors.

In the present embodiment, it is preferable that the thickness t2 of the color filters 61R fall in the range of 0.8 to 0.9 μm, and that the thickness t3 of the green color filters 61Gr and 61Gb as well as of the blue color filters 61B fall in the range of 0.4 to 0.6 μm. In the case of forming the green color filters and the blue color filters to have mutually different thicknesses, it is preferable that the thickness of the green color filters 61Gr and 61Gb fall in the range of 0.4 to 0.5 μm, and the thickness of the blue color filters 61B fall in the range of 0.5 to 0.6 μm.

As described above, the solid-state imaging device 51 has the red color filters having a thickness determined according to the wavelengths of light that can pass through the red color filters. With this arrangement, the amount of light that transmits the red color filters is increased as compared with that in the solid-state imaging device 1 according to the first embodiment and the loss of collection efficiency of light to the photodiodes is further prevented.

### <Manufacturing Method>

Next, a description is given of a manufacturing method for the solid-state imaging device 51 according to the present embodiment.

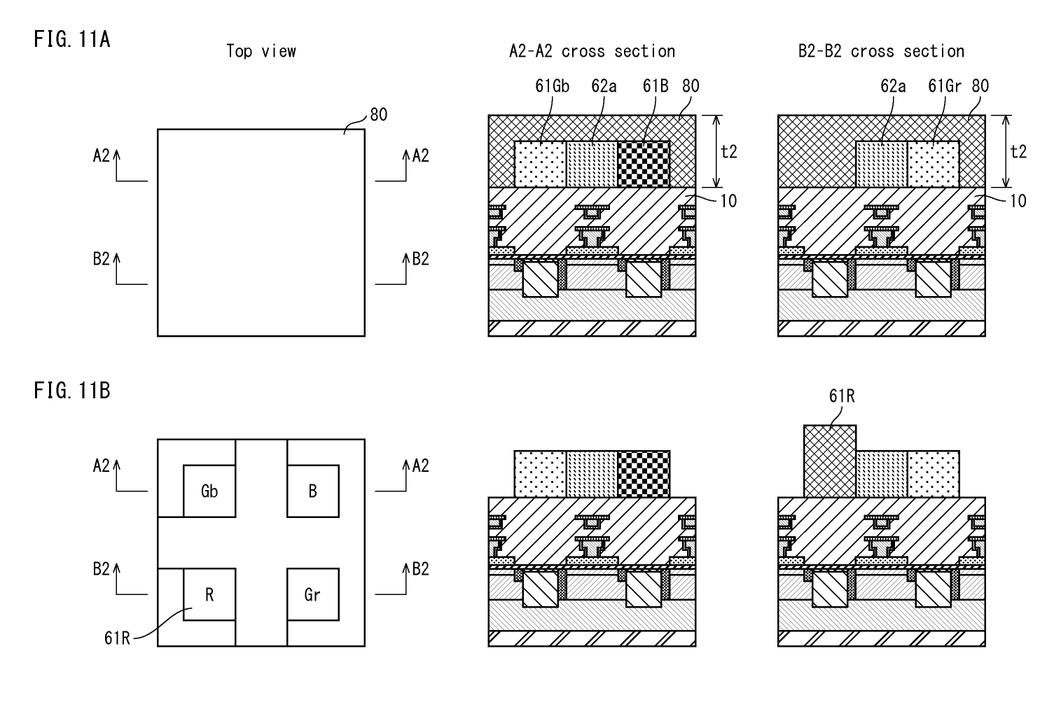

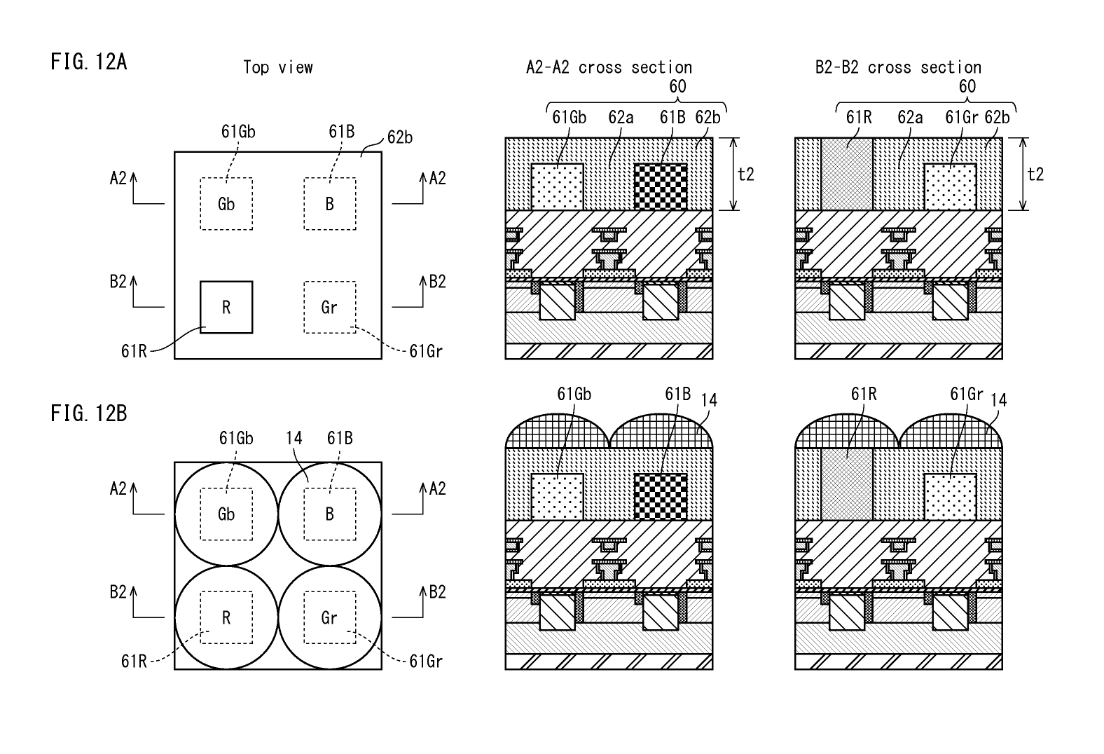

FIGS. 11-12 are schematic sectional views used to explain the manufacturing method for the solid-state imaging device 51.

The manufacturing method of the solid-state imaging device 51 is identical to the manufacturing method of the solid-state imaging device 1 according to the first embodiment in that both the methods commonly have: the first step of manufacturing a matrix of photodiodes in the silicon substrate; the second step of forming the transparent insulating layer 10 in which the wiring lines are embedded; the third step of forming the color filter layer 60 including the color filters 61; and the fourth step of forming microlenses.

On the other hand, the difference with the manufacturing method of the solid-state imaging device 1 according to the first embodiment lies in that the red color filters of the solid-state imaging device 51 are formed to have a thickness t2 that is greater than the thickness t3 of the green and blue color filters 61Gr-61B. For the sake of simplicity, no description is given of the same steps as those in the manufacturing method of the solid-state imaging device 1 shown in FIGS. 4-9. The following description begins with the step of forming red color filters 61R, which is one step in the third step.

### <<Third Step>>

### (Color Filter Forming Step)

A red color filter material 80 containing photosensitizer is applied to the regions of the transparent insulating layer 10 excluding where the low-refractive-index material 62a and the color filters 61Gr, 61Gb, and 61B are present (FIG. 11A). In this step, the color filter material 80 is applied until the height of the applied material 80 is greater than that of the color filters 61Gr, 61Gb, and 61B (until reaching the height t2 measured from the transparent insulating layer 10).

Then, the color filter material 80 is patterned to form color filters 61R (FIG. 11B).

### (Second Sub-Step of Disposing Low-Refractive-Index Material)

First, low-refractive-index material 62b of identical compositions as the low-refractive-index material 62a is applied to the regions of the transparent insulating layer 10 excluding where the low-refractive-index material 62a and the color filters 61Gr, 61Gb, and 61B are present (FIG. 12A). In this step, the low-refractive-index material 62b is applied until the upper surface of the applied material 62b reaches the height equal to the upper surfaces of the color filters 61R (i.e., equal to the height t2 measured from the transparent insulating layer 10). Through this sub-step, the color filters 61R, 61Gr, 61Gb, and 61B are surrounded by the low-refractive-index material 62, which has been applied as the low-refractive-index materials 62a and 62b.

### <<Fourth Step>>

Finally, microlenses 14 are formed on the respective color filters 61R, 61Gr, 61Gb, and 61B (FIG. 12B).

Through the above steps, the solid-state imaging device 51 is manufactured.

### Third Embodiment

### Schematic Structure

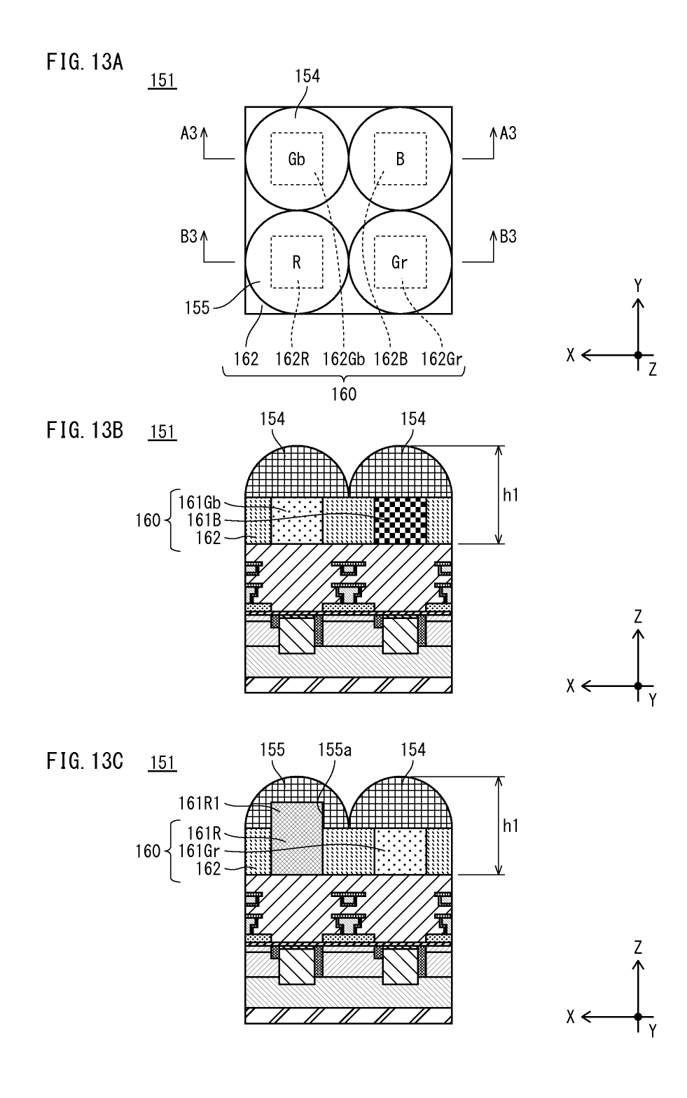

Next, a description is given of a solid-state imaging device 151 according to a third embodiment of the present disclosure, with reference to FIGS. 13A-13C.

FIG. 13A is a top view showing part of the solid-state imaging device according to the third embodiment. FIG. 13B is a sectional view taken along the arrowed line A3-A3 of FIG. 13A, whereas FIG. 13C is a sectional view taken along the arrowed line B3-B3 of FIG. 13A.

The present embodiment is identical to the second embodiment in that the red color filters are thicker than the color filters of the other colors.

Yet, the present embodiment differs from the second embodiment according to which the microlenses 14 are disposed on the flat surface of the color filter layer 60, the flat surface being formed by filling with the low-refractive-index material 62 to reach the height of the top surfaces of the red color filters 61R. In contrast, according to the present embodiment, the low-refractive-index material 162 is filled to reach the height of the top surfaces of the color filters other than red (namely to the top surfaces of the color filters 161Gr-161B). That is, the red color filters 161R projects beyond the other regions, which means that the surface of the color filter layer 160 has projections and depressions. The microlenses are disposed on that uneven surface of the color filter layer 160. For the sake of simplicity, the components identical to those of the solid-state imaging device 51 shown in FIGS. 10A-10C are denoted by the same reference signs and a description thereof is omitted.

### <Structure of Color Filters>

According to the present embodiment, the refractive index of the color filters 161R is 1.9, whereas the refractive index of the color filters 161Gr, 161Gb, and 161B is 1.5.

On the color filter layer 160, first microlenses 154 are disposed one for each of the color filters 161Gr-161B, which are of the colors other than red, and also second microlenses 155 are disposed one for each of the red color filters 161R.

Each second microlens 155 has a concaved portion 155a formed in the bottom surface and the concaved portion 155a is shaped to conform to the projecting portion 161R1 of the color filter 161R. The projecting portion 161R1 is received within the concaved portion.

The first and second microlenses 154 and 155 are made from a transparent organic material having the refractive index 1.5. That is, the projecting portion 161R1 of each color filter 161R is surrounded by the materials having a lower refractive index than that of the color filters 161R themselves. Therefore, the entire color filter 161R including the projecting portion 161R1 acts as a waveguide.

In the manner described above, in the case where the color filters of different thicknesses are provided, portions of the thicker color filters (i.e., portions projecting beyond the height of the thinner color filters) may be located inside the microlenses. This embodiment achieves the same advantages as that achieved by the second embodiments. In addition, this embodiment achieves that the overall height h1 of the color filter layers and the microlenses is smaller as compared with the second embodiment, because portions of the thicker color filters are located inside the microlenses. This advantage is effective for downsizing the solid-state imaging device.

### Fourth Embodiment

### Schematic Structure

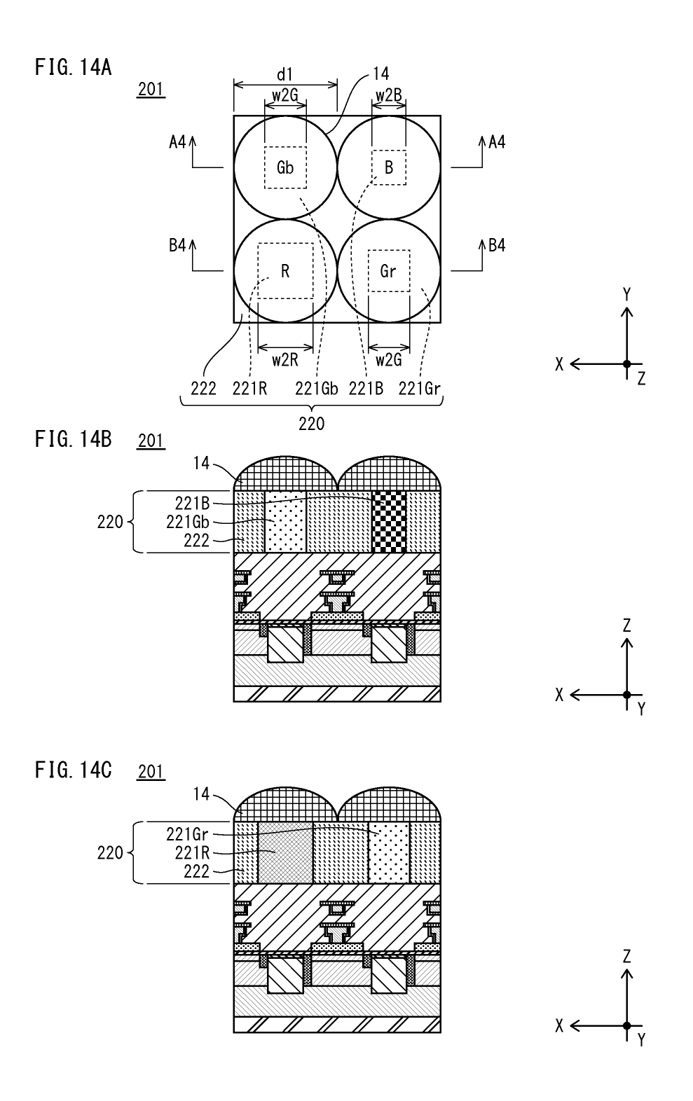

Next, a description is given of a solid-state imaging device 201 according to a fourth embodiment of the present disclosure, with reference to FIGS. 14A-14C.

FIG. 14A is a top view showing part of the solid-state imaging device according to the fourth embodiment. FIG. 14B is a sectional view taken along the arrowed line A4-A4 of FIG. 14A, whereas FIG. 14C is a sectional view taken along the arrowed line B4-B4 of FIG. 14A.

Different from the first embodiment according to which the color filters 21R-21B are all equal in width, the color filters according to the present embodiment have different widths for the respective colors. For the sake of simplicity, the components identical to those of the solid-state imaging device 1 shown in FIGS. 1A-1C are denoted by the same reference signs and a description thereof is omitted.

### <Structure of Color Filters>

According to the present embodiment, the refractive index of the color filters 221R is 1.9, whereas the refractive index of the color filters 221Gr, 221Gb, and 221B is 1.5.

In the color filter layer 220, the width w2B of the blue color filters 221B is smaller than the width w2G of the green color filters 221Gr and 221Gb. In addition, the width w2G of the green color filters 221Gr and 221Gb is smaller than the width w2R of the red color filters 221R. Yet, the widths w2R, w2B, and w2G are all smaller than the diameter d1 of the microlenses 14.

In the present embodiment, the width w2G of the green color filters 221Gr and 221Gb is 0.6 μm, whereas the width of the red color filters 221R is 0.8 μm and the width w2B of the blue color filters 221B is 0.45 μm.

As described above, the widths w2R-w2B are determined to be close to the sizes of the respective wavelengths (which are computed in consideration of the respective refractive indexes) of light that passes through the respective color filters 221R-221B. This ensures the propagation mode of each of the color filters 221R-221B to be single-mode propagation or nearly single-mode propagation, thereby ensuring divergence of light having passed the respective color filters 221R-221B to be suppressed.

With respect to the red color filters 221R, in addition, the single-mode propagation or nearly single-mode propagation is also effective to suppress occurrence of flare. The details of this advantage are described below.

For example, digital cameras are provided with an infrared cut-off filter disposed between the camera lens and the solid-state imaging device housed in the casing. The infrared cut-off filter reflects infrared radiation while allowing visible light to pass through. Yet, depending on the angle of incidence, the infrared cut-off filter may reflect a portion of visible light, the portion being closer to the infrared wavelengths.

Of the light incident on the infrared cut-off filter from the camera lens, visible light passes through the infrared cut-off filter. Yet, a portion of the transmitted visible light is reflected and diffracted by the microlenses disposed on the chip surface and travels back toward the infrared cut-off filter. Such a portion of light is reflected by the infrared cut-off filter and enters the solid-state imaging device at an angle to be ultimately received by the photoelectric converter regions. Reception of such light results in occurrence of flare, which is a type of noise.

Note that the blue pixels as well as the green pixels of the solid-state imaging device are associated with little risk of flare caused by oblique incidence of red light because the blue or green color filters of the respective pixels absorb red light. On the other hand, the red pixels involve a higher risk of flare caused by oblique incidence of red light because the red filters of the respective pixels passes red light.

Therefore, by ensuring the propagation mode in the red color filters 221R to be nearly single-mode propagation, red light obliquely incident is eliminated by interference of light within the color filters 221R. This is effective to suppress occurrence of flare.

### Fifth Embodiment

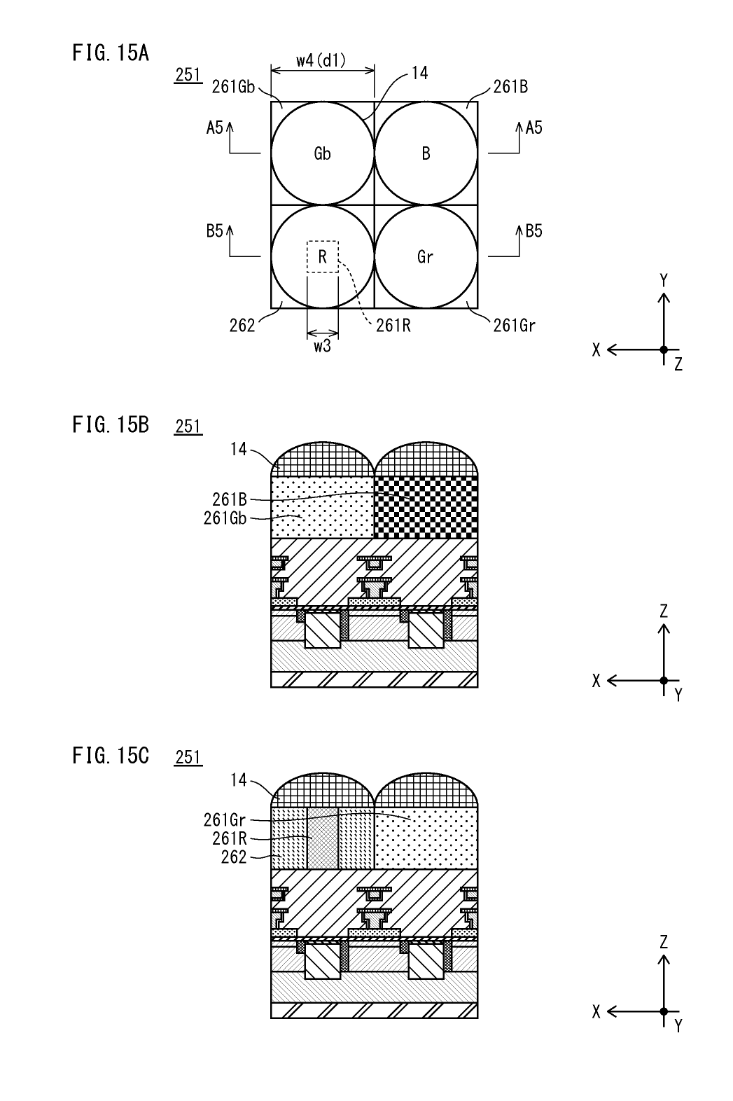

Next, a description is given of a solid-state imaging device 251 according to a fifth embodiment of the present disclosure, with reference to FIGS. 15A-15C.

FIG. 15A is a top view showing part of the solid-state imaging device according to the fifth embodiment. FIG. 15B is a sectional view taken along the arrowed line A5-A5 of FIG. 15A, whereas FIG. 15C is a sectional view taken along the arrowed line B5-B5 of FIG. 15A.

According to the fourth embodiment, all the color filters 221 have a width that is smaller than the diameter d1 of the microlenses 14 and are surrounded by the low-refractive-index material 222. In contrast, according to the present embodiment, while the red color filters 261R have the width w3 that is smaller than the diameter d1 of the microlenses 14 and are surrounded by the low-refractive-index material 262, the green and blue color filters 261Gr-261B have the width w4 that is equal to the diameter d1 and are not surrounded by the low-refractive-index material 262. For the sake of simplicity, the components identical to those of the solid-state imaging device 201 shown in FIGS. 14A-14C are denoted by the same reference signs and a description thereof is omitted.

In the manner described above, depending on the specifications and applications of the solid-state imaging device, it may be applicable to surround only the red color filters 261R by the low-refractive-index material 262.

In the present embodiment, the width w3 of the red color filters 261R is in the range of 0.4 to 0.6 μm, and the width w4 of the green and blue color filters 261Gr-261B is in the range of 1.5 μm.

### Sixth Embodiment

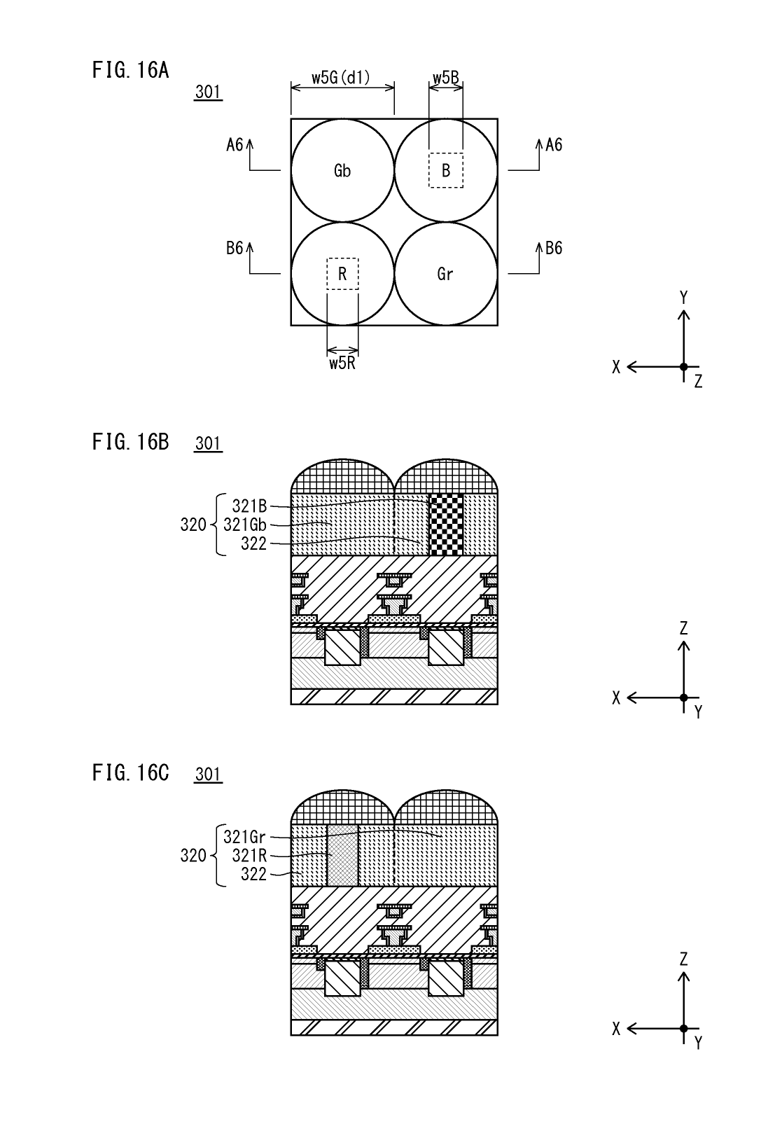

Next, a description is given of a solid-state imaging device 301 according to a sixth embodiment of the present disclosure, with reference to FIGS. 16A-16C.

FIG. 16A is a top view showing part of the solid-state imaging device according to the sixth embodiment. FIG. 16B is a sectional view taken along the arrowed line A6-A6 of FIG. 16A, whereas FIG. 16C is a sectional view taken along the arrowed line B6-B6 of FIG. 16A.

According to the fourth embodiment, all the color filters 221 have a width that is smaller than the diameter d1 of the microlenses 14 and are surrounded by the low-refractive-index material 222. In contrast, the present embodiment differs in that: the green color filters 321Gr and 321Gb have the width w5G that is equal to the diameter d1 and not surrounded by a low-refractive-index material; and that the red and blue color filters 321R and 321B respectively have the widths w5R and w5B that are smaller than the diameter d1 of the microlenses 14 and are surrounded by a green color filter material 322 that is identical to the material of the color filters 321Gr and 321Gb. For the sake of simplicity, the components identical to those of the solid-state imaging device 201 shown in FIGS. 14A-14C are denoted by the same reference signs and a description thereof is omitted.

In the present embodiment, the refractive index of the color filters 321R and 321B is 1.6, and the refractive index of the green color filter material 322 is 1.2. Hence, the refractive index of the color filters 321Gr and 321Gb is also 1.2. In this embodiment, the refractive index of the green color filter material 322 is still lower than the refractive index of the color filters 321R and 321B, and therefore the color filters 321R and 321B act as waveguides. That is, this embodiment achieves the same advantageous effect as that achieved by the color filters 221R and 221B according to the fourth embodiment.

In the manner described above, the present embodiment uses the green color filter material as a low-refractive-index material, which means that a fewer types of materials are used to manufacture the color filter layer as compared with the fourth embodiment. Therefore, the present embodiment allows the manufacturing steps to be simplified.

### Seventh Embodiment

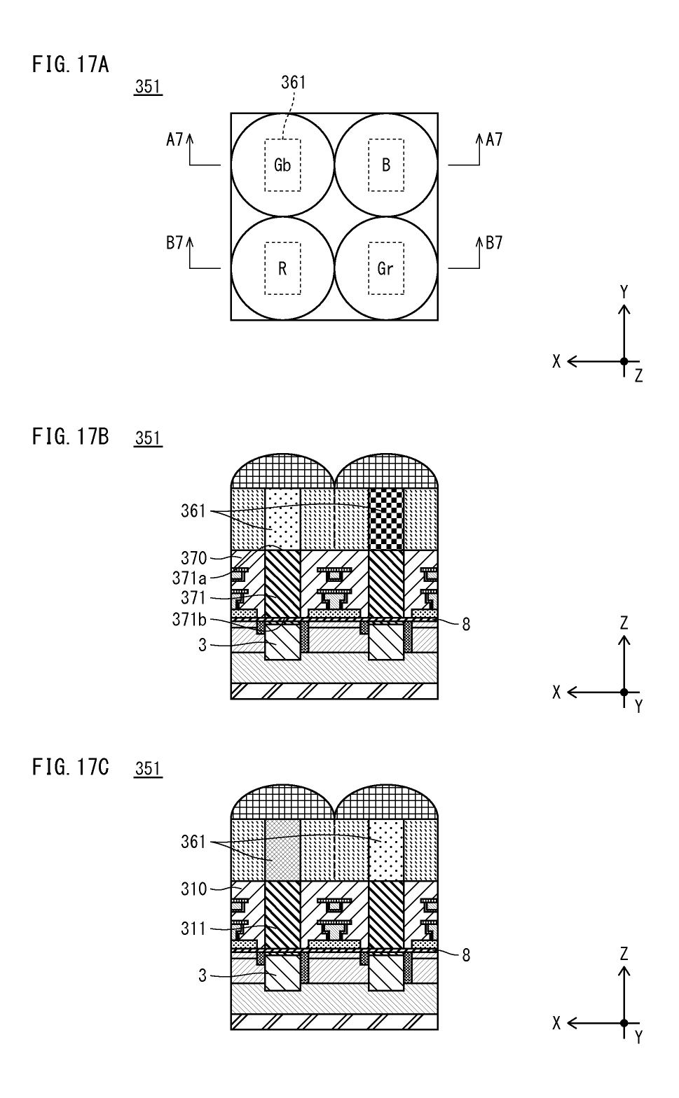

Next, a description is given of a solid-state imaging device 351 according to a seventh embodiment of the present disclosure, with reference to FIGS. 17A-17C.

FIG. 17A is a top view showing part of the solid-state imaging device according to the seventh embodiment. FIG. 17B is a sectional view taken along the arrowed line A7-A7 of FIG. 17A, whereas FIG. 17C is a sectional view taken along the arrowed line B7-B7 of FIG. 17A.

The present embodiment differs from the first embodiment in that optical waveguide regions 371 are disposed in a transparent insulating layer 370. More specifically, each optical waveguide region 371 is disposed between a color filter 361 and a photodiode 3. For the sake of simplicity, the components identical to those of the solid-state imaging device 1 shown in FIGS. 1A-1C are denoted by the same reference signs and a description thereof is omitted.

The optical waveguide regions 371 are made of silicon nitride (refractive index: 1.9).

The regions of the transparent insulating layer 370 other than where the optical waveguide regions 371 are disposed are made of silicon oxide (refractive index: 1.45). That is, the optical waveguide regions 371 are surrounded by silicon oxide having a lower refractive index than that of the optical waveguide regions 371 themselves, so that the boundaries between the optical waveguide regions 371 and the silicon oxide reflect light by total reflection or Fresnel reflection.

The upper surface 371a of each optical waveguide region 371 is shaped to conform to the bottom surface of a corresponding color filter 361. The bottom surface 371b of the optical waveguide region 371 has the size of the upper surface of a corresponding photodiode 3 and faces toward the photodiode 3 via the insulating film 8. With this structure, light emitted from the color filters 361 travels toward the photodiodes 3 via the optical waveguide regions 371 without leaking between the color filters 361 and the optical waveguide regions 371 or between the optical guides 371 and the photodiodes 3.

The optical waveguide regions 371 are manufactured by, for example, forming holes in the transparent insulating layer 370 by dry etching and filling the holes with silicon nitride.

According to the present embodiment, the optical waveguide regions 371 are provided in the transparent insulating layer 370 that is located between the color filters 361 and the photodiodes 3. This structure suppresses the divergence of light emitted from the color filters to a greater extent than by the solid-state imaging device 1 according to the first embodiment. Therefore, occurrence of color crosstalk is suppressed even better.

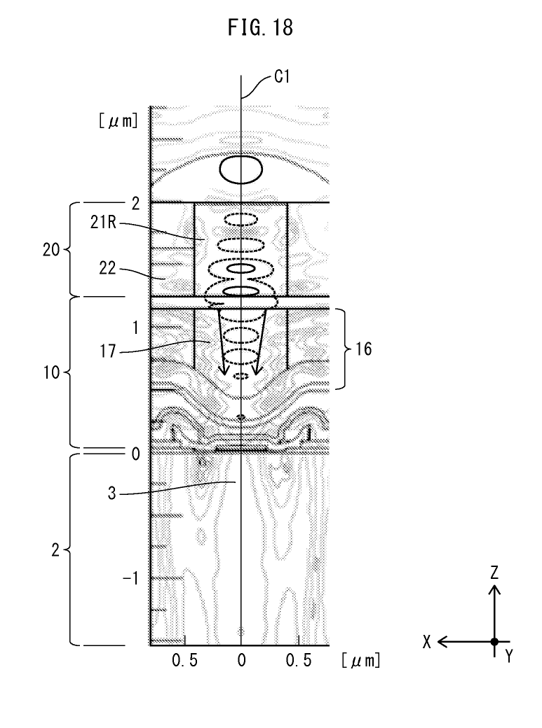

FIG. 18 is obtained by the simulation run to confirm the suppression of light divergence by a solid-state imaging device having the optical waveguide regions as described above. For the purpose of comparison, the solid-state imaging device shown in FIG. 18 is basically identical in structure to the solid-state imaging device shown in FIG. 3B, except the optical waveguide regions 17 disposed inside the transparent insulating layer 10.

As shown in FIG. 18, light as emitted from the color filter 21R enters the optical waveguide region 17 thorough which the light is guided downward (toward the photodiode 3). In comparison with the simulation result shown in FIG. 3B, the simulation result shown in FIG. 18 indicates that the divergence of light emitted from the color filter 21R is suppressed to a greater extent.

The above simulation demonstrates that the provision of optical waveguide regions in the transparent insulating layer is effective to better suppress the divergence of light emitted from the color filters.

Note that light is shown to be converged in the optical waveguide region 17, and this convergence of light is by the action of the intra-layer lens 16.

Up to this point, the solid-state imaging devices and manufacturing methods according to the present invention have been described by way of specific embodiments. Naturally, however, the present invention is not limited to those specific embodiments.

### [Modifications]

For example, the following modifications may be made.

(1) Although the above embodiments are described by way of the CCD solid-state imaging devices, the present invention is not limited to such and applicable to CMOS solid-state imaging devices as well.

(2) The red, green, and blue color filters may mutually differ in refractive index and the refractive indexes may be determined appropriately to the specifications and applications of the solid-state imaging devices.

(3) According to the above embodiments, the low-refractive-index material is organic glass material but not limited to such. For example, the low-refractive-index material may be an inorganic transparent material containing silicon oxide.

(4) According to the above embodiments, the color filters of the respective colors are surrounded by the low-refractive-index material of the same type. However, the present invention is not limited to such. For example, different low-refractive-index materials may be used for the different colors of the color filters.

(5) According to the above embodiments, the photoelectric converters comprise photodiodes. However, the photoelectric converters are not limited to such structure.

(6) According to the above embodiments, the manufacturing methods for solid-state imaging devices according to the present invention are described. However, the manufacturing methods of the solid-state imaging devices according to the present invention are not limited to those described above. Depending on the specifications and applications of the solid-state imaging devices, an appropriate manufacturing method therefor can be selected.

For example, according to the above embodiments, the low-refractive-index material is formed in the color filter layer through two steps, namely the first and second sub-steps. Alternatively, however, the low-refractive-index material may be formed in a single step. In this modification, the low-refractive-index material may be formed either before or after the step of forming color filters.

Note that in the case where a plurality of different low-refractive-index materials are used for, for example, color filters of the respective colors, a step of forming low-refractive-index material needs to be performed for each color.

### INDUSTRIAL APPLICABILITY

The present disclosure is useful to provide solid-state imaging devices offering high image quality.

### REFERENCE SIGNS LIST

1 solid-state imaging device
F1, F2 focus
2 silicon substrate
3 photodiode
4 transfer channel
9 transfer electrode
10 insulating layer
11, 12 wiring line
14 microlens
20 color filter layer
21 color filter
22 low-refractive-index material
22a, 22b low-refractive-index material
30 pixel
40 resist pattern
51, 100, 151, 201, 251, 301, 351 solid-state imaging device
60, 160, 220 color filter layer
61, 121, 161, 221, 261, 321, 361 color filter
62, 162, 222, 262 low-refractive-index material
154, 155 microlens
155 microlens
370 transparent insulating layer
371 optical waveguide region

1. A solid-state imaging device comprising:
a semiconductor substrate including a matrix of photoelectric converters disposed therein;
a transparent insulating layer disposed on the semiconductor substrate and including wiring lines embedded therein;
a color filter layer disposed on the transparent insulating layer and including a color filter for each of a plurality of colors of the respective photoelectric converters; and
a plurality of microlenses disposed on the color filter layer, one for each color filter, wherein
in a plan view, the color filter of at least one color is smaller in area size than the corresponding microlens, and
in the color filter layer, the color filter of the at least one color is surrounded by a low-refractive-index material having a lower refractive index than a refractive index of the color filter.

2. The solid-state imaging device according to claim 1, wherein
one of the colors of the respective photoelectric converters is red, and
the color filter of the at least one color is a red color filter that transmits red light.

3. The solid-state imaging device according to claim 1, further comprising:
an optical waveguide disposed in the transparent insulating layer and between the color filter of the at least one color and the photoelectric converter disposed below the color filter, the optical waveguide being made from a transparent material having a higher refractive index than a refractive index of any other region.

4. The solid-state imaging device according to claim 1, wherein
the low-refractive-index material is an organic transparent material containing organic glass or an inorganic transparent material containing silicon oxide.

5. The solid-state imaging device according to claim 2, wherein
the red color filter is thicker than the color filters that transmit light of a color other than red.

6. The solid-state imaging device according to claim 2, wherein
the photoelectric converters are all equal in area size in a plan view, and
the red color filter is smaller in a plan view than the color filters that transmit light of a color other than red.

7. The solid-state imaging device according to claim 1, wherein
the at least one color comprises all of the plurality of colors.

8. The solid-state imaging device according to claim 1, wherein
the color filter of the at least one color has a width in a range of 0.4 to 1.0 μm in a row direction as well as in a column direction.

9. The solid-state imaging device according to claim 7, wherein
the photoelectric converters are all equal in size in a plan view,
the plurality of colors are red, green, and blue, and
the red color filter and the blue color filter that respectively transmit red light and blue light are smaller in a plan view than the green color filter that transmits green light.

10. The solid-state imaging device according to claim 1, wherein
at least one of a plurality of pixels is configured such that the color filter of the at least one color positionally coincides with a center of the corresponding microlens in a plan view.

11. The solid-state imaging device according to claim 1, wherein
the color filter of the at least one color has a thickness equal to an integral multiple of a half of a wavelength of the color.

12. The solid-state imaging device according to claim 5, wherein
the red color filter is thicker than the color filters that transmit light of the other color and thus projects beyond upper surfaces of the other color filters, and
the microlens disposed over the red color filter has a bottom surface concaved to conform to the projecting portion of the red color filter.

13. The solid-state imaging device according to claim 1, wherein
the at least one color comprises one or more of the plurality of colors, and
the color filter of a color other than the one or more of the plurality of colors is made from a filter material having a lower refractive index than a refractive index of a filter material of each color filter of the one or more colors.

14. A manufacturing method for a solid-state imaging device, the manufacturing method comprising:
a first step of forming a matrix of photoelectric converters in a semiconductor substrate;
a second step of forming, on the semiconductor substrate, a transparent insulating layer containing wiring lines embedded therein;
a third step of forming, on the transparent insulating substrate, a color filter layer including a color filter for each of a plurality of colors of the respective photoelectric converters; and
a fourth step of forming a plurality of microlenses, one for each color filter, wherein
the third step includes:
a step of forming the color filters each in a size smaller than the corresponding microlens in a plan view; and
a step of disposing a low-refractive-index material to surround each color filter, the low-refractive-index material having a refractive index lower than a refractive index of the color filter.

15. The manufacturing method according to claim 14, wherein
the step of disposing the low-refractive-index material includes:
a first sub-step of disposing the low-refractive-index material at regions between rows and columns of the color filters at a predetermined interval; and
a second step of disposing the low-refractive-index material at the other regions between the rows and columns of the color filters.
